(19) United States
(12) Patent Application Publication
(10) Pub. No.: US 2006/0044430 A1
(43) Pub. Date: Mar. 2, 2006

(54) Thermoelectric cooling for imagers

(76) Inventor: Chandra Mouli, Boise, ID (US)

Correspondence Address: DICKSTEIN SHAPIRO MORIN & OSHINSKY LLP, 2101 L STREET, NW, WASHINGTON, DC, 20037, US

(21) Appl. No.: 10/923,701

(22) Filed: Aug. 24, 2004

(51) Int. Cl. H04N 5/335

(52) U.S. Cl. 348/294

(57) ABSTRACT

An imager is provided with a thermoelectric cooler. The cooler is formed on the back side of the imager to thermoelectrically cool areas of the imager. The cooler removes heat from targeted regions where heat is generated and conducts the heat away from sensitive pixel array regions. Accordingly, dark current is reduced by thermoelectrically cooling the imager.

### FIELD OF INVENTION

The invention relates to imaging devices and specifically to thermoelectric cooling for imaging devices.

### BACKGROUND OF THE INVENTION

Typically, a digital imager array includes a focal plane array of pixel cells, each one of the cells including a photoconversion device such as, e.g., a photogate, photoconductor, or a photodiode. In a complementary metal oxide semiconductor (CMOS) imager a readout circuit is connected to each pixel cell which typically includes a source follower output transistor. The photoconversion device converts photons to electrons which are typically transferred to a floating diffusion region connected to the gate of the source follower output transistor. A charge transfer device (e.g., transistor) can be included for transferring charge from the photoconversion device to the floating diffusion region. In addition, such imager cells typically have a transistor for resetting the floating diffusion region to a predetermined charge level prior to charge transference. The output of the source follower transistor is a voltage output on a column line when a row select transistor for the row containing the pixel is activated.

Exemplary CMOS imaging circuits, processing steps thereof, and detailed descriptions of the functions of various CMOS elements of an imaging circuit are described, for example, in U.S. Pat. No. 6,140,630, U.S. Pat. No. 6,376,868, U.S. Pat. No. 6,310,366, U.S. Pat. No. 6,326,652, U.S. Pat. No. 6,204,524, and U.S. Pat. No. 6,333,205, assigned to Micron Technology, Inc. The disclosures of each of the forgoing patents are herein incorporated by reference in their entirety.

FIG. 1 illustrates a cross sectional view of a pixel for a CMOS imager. In the illustrated imager, when incident light strikes the surface of a photodiode 49, electron/hole pairs are generated in the p-n junction (between regions 21 and 23) of the photodiode 49. The generated electrons are collected in the n-type region of the photodiode. The photo charge moves from the initial charge accumulation region (e.g., region 23) to a charge collection region, typically a floating diffusion region 16, or it may be transferred to the floating diffusion region 16 via a transfer transistor 26. The charge at the floating diffusion region 16 is converted to a pixel output voltage by a source follower transistor (not shown).

The illustrated imager may experience leakage, called dark current, which occurs when charge is not adequately accumulated in the photodiode 49. Dark current results in distortion of the image. Dark currents exist due to generation/recombination centers inside the depletion region between regions 21 and 23 of photodiode 49. Dark currents have thermodynamic lower limits and place limitations on sensitivity. Several factors may contribute to dark current, including defects, high local electric fields or transistor switching.

Dark current is strongly correlated to temperature. Thermal conductivity of silicon is generally very poor. Therefore, fast logic devices in CMOS circuitry may create a large leakage current that increases the local temperature where they are located and consequently increases dark current. For example, analog to digital converter (ADC) circuits are known to cause a large standby current in image sensors. A local high temperature source, such as an ADC, affects the pixel array by increasing dark current.

The principle of thermoelectric cooling dates back to the discovery of the Peltier effect by Jean Peltier in 1834. Electric current flow always results in creating heat (joule heating). Peltier observed that when electric current passed across the junction of two dissimilar conductors (“thermocouple”) there was a heating effect that could not be explained by Joule heating alone. More interesting was the fact that depending on the direction of the current, the overall effect could be either heating or cooling. This effect can be harnessed to transfer heat, creating a heater or a cooler. This discovery was not fully appreciated until late in the 20th century.

When two conductors are placed in electric contact, electrons flow out of the one in which the electrons are less bound, into the one where the electrons are more bound, due to the difference in the Fermi level between the two conductors. When dissimilar conductors with different Fermi levels make contact, electrons flow from the conductor with the higher level to the one with the lower level until the change in the electrostatic potential brings the Fermi level to an equilibrium constant value, which is the contact potential. Current passing across a semiconductor junction results either in forward or reverse bias which results in a temperature gradient.

Semiconductors are the materials of choice to build these thermoelectric coolers. Bismuth Telluride (Bi₂Te₃) that has been suitably doped to provide individual blocks or elements having distinct “N” and “P” characteristics. Other thermoelectric materials include Lead Telluride (PbTe), Silicon Germanium (SiGe), and Bismuth-Antimony (Bi—Sb) alloys. Bismuth Telluride is highly anisotropic. Its electrical resistance is about four times greater parallel to the axis of crystal growth than perpendicular to it. Thermal conductivity, on the other hand, is about double parallel to the crystal-growth axis that perpendicular direction. Hence the anisotropic behavior of resistance is greater than that of thermal conductivity, and the highest figure or merit occurs in the parallel orientation. Another interesting characteristic of Bismuth Telluride is that Bismuth Telluride (Bi₂Te₃) crystals are made up of hexagonal layers of similar atoms. While alternate layers of Bismuth and Tellurium are held together by strong covalent bonds, adjacent layers of Tellurium are held together only by weak van der Waals bonds. As a result, crystalline Bismuth Telluride cleaves readily along these Tellurium-Tellurium layers (like Mica sheets). The cleavage planes generally run parallel to the C-axis, so the material is quite strong when assembled into a thermoelectric cooling module.

The thermoelectric cooler shown in FIG. 2 includes a cooling plate 100, insulators 101, 105 conducting materials 102, 104, a p/n semiconductor including a p-type region 103 and an n-type region 107, and a heat sink 106. Voltage is applied to the free ends of two different conducting materials (i.e., plate 100, sink 106), resulting in a flow of electricity through the semiconductor. The flow of DC current across the p/n junction 109 of the semiconductor creates a temperature difference. As a result of the temperature difference, Peltier cooling causes heat to be absorbed from the vicinity of the cooling plate 100, and to move to the other end of the device (i.e., heat sink 106).

It has been proposed to employ thermoelectric cooling for certain logic devices (see U.S. Pat. No. 6,614,109). The technology has not been employed, however, in imagers or targeted to specific areas of an imager. A thermoelectric cooler for imaging devices is needed to reduce dark current to obtain high sensitivity (i.e., high signal to noise ratio) and efficiency.

### BRIEF SUMMARY OF THE INVENTION

Exemplary embodiments of the invention provide an imager with a thermoelectric cooler. The thermoelectric cooler is formed on the back side of the imager and in some embodiments, thermoelectrically cools specific areas of the imager. The cooler removes heat from targeted regions of the imager where heat is generated and conducts that heat away from the sensitive pixel array region of the imager. Accordingly, dark current is reduced by thermoelectrically cooling the imager.

### BRIEF DESCRIPTION OF THE DRAWINGS

The above and other features and advantages of the invention will be more readily understood from the following detailed description which is provided in connection with the accompanying drawings, in which:

FIG. 1 is a cross-sectional view of an imager pixel;

FIG. 2 is a side view of a thermoelectric cooler;

FIG. 3 is a block diagram of an imaging device according to an exemplary embodiment of the invention;

FIG. 4 is a bottom view of an imaging device constructed according to an exemplary embodiment of the invention;

FIG. 5 is a bottom view of an imaging device constructed according to another exemplary embodiment of the invention;

FIG. 6 is a cross-sectional view of an imager pixel constructed in accordance with an exemplary embodiment of the invention;

FIGS. 7a-7h illustrate a process of forming an imaging device in accordance with another exemplary embodiment of the invention; and

FIG. 8 is a block diagram of a processing system according to an exemplary embodiment of the invention.

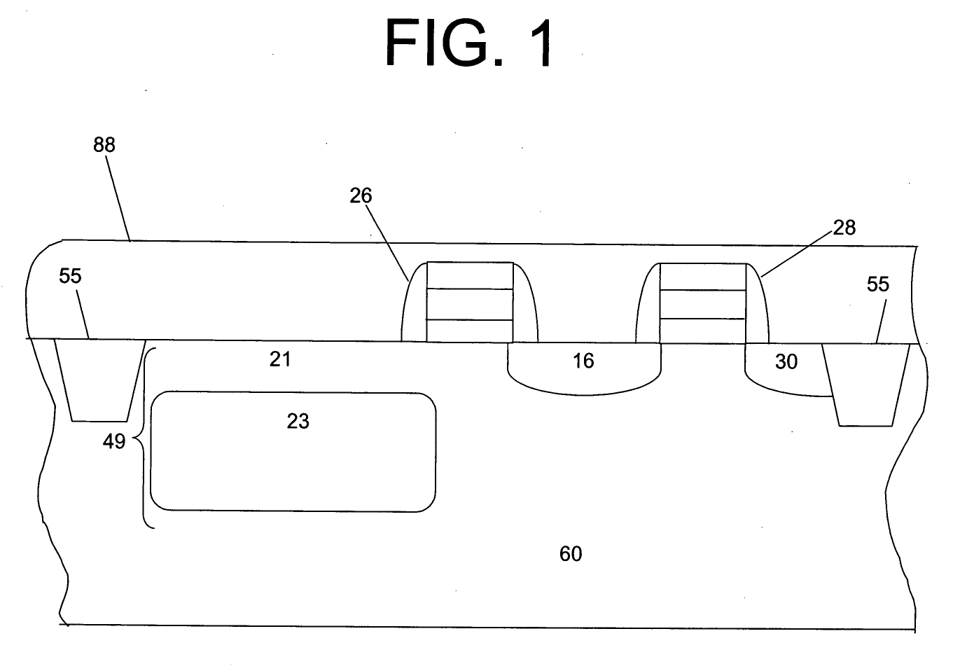

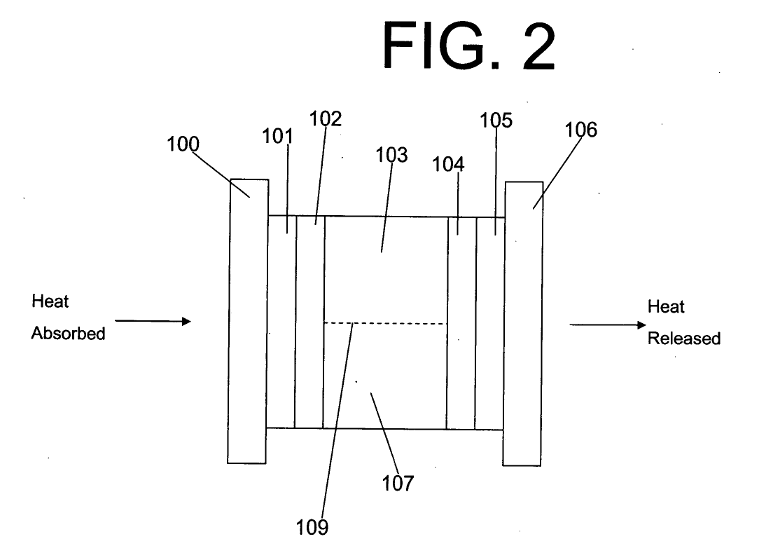

### DETAILED DESCRIPTION OF PREFERRED EMBODIMENTS

In the following detailed description, reference is made to the accompanying drawings, which form a part hereof and show by way of illustration specific exemplary embodiments in which the invention may be practiced. These embodiments are described in sufficient detail to enable those skilled in the art to practice the invention, and it is to be understood that other embodiments may be utilized, and that structural, logical, and electrical changes may be made without departing from the spirit and scope of the present invention. The progression of processing steps described is exemplary of embodiments of the invention; however, the sequence of steps is not limited to that set forth herein and may be changed as is known in the art, with the exception of steps necessarily occurring in a certain order.

The terms “wafer” and “substrate,” as used herein, are to be understood as including silicon, silicon-on-insulator (SOI) or silicon-on-sapphire (SOS) technology, doped and undoped semiconductors, and other semiconductor structures. Furthermore, when reference is made to a “wafer” or “substrate” in the following description, previous processing steps may have been utilized to form regions, junctions, or material layers in or over the base semiconductor structure or foundation. In addition, the semiconductor need not be silicon-based, but could be based on silicon-germanium, germanium, gallium arsenide or other semiconductors.

The term “pixel,” as used herein, refers to a photo-element unit cell containing a photoconversion device and associated transistors for converting photons to an electrical signal. The pixels discussed herein are illustrated and described as inventive modifications to four transistor (4T) pixel circuits for the sake of example only. It should be understood that the invention may be used with other pixel arrangements having fewer (e.g., 3T) or more (e.g., 5T) than four transistors. Although the invention is described herein with reference to the architecture and fabrication of one pixel, it should be understood that this is representative of a plurality of pixels in an array of an imager device. In addition, although the invention is described below with reference to a CMOS imager, the invention has applicability to other solid state imaging devices. The following detailed description is, therefore, not to be taken in a limiting sense.

According to the invention, a thermoelectric cooler is integrated into an imaging device by forming a p/n junction on the back (bottom) side of a wafer prior to any front (top) side fabrication processing. Since the p/n junctions are very large area structures, they can be easily fabricated on the back side of the wafer and designed in such a manner to withstand all the heat steps typically involved in conventional fabrication processing.

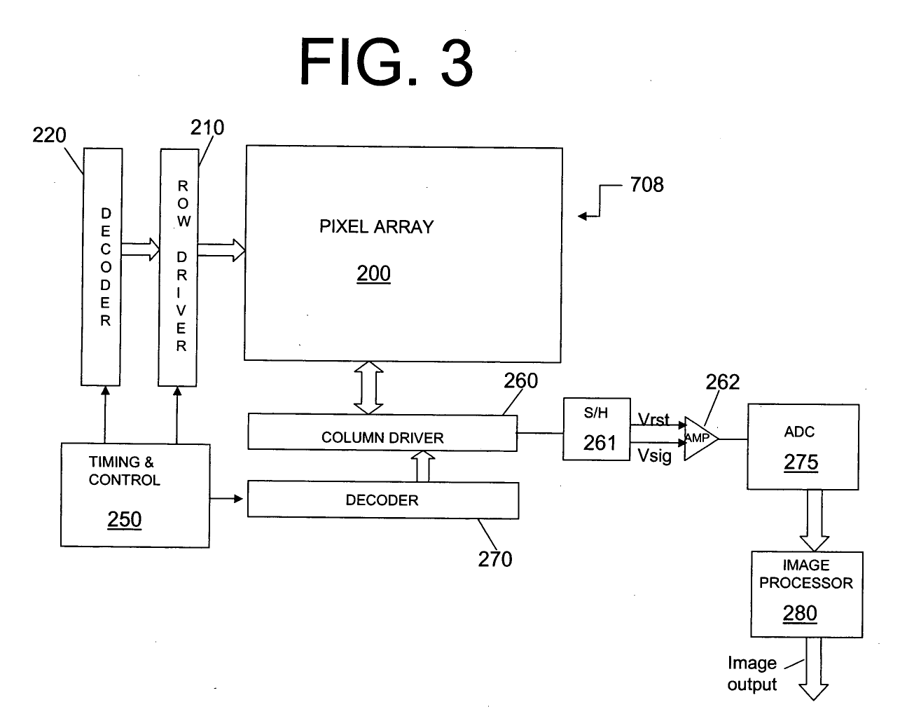

Now referring to the figures, where like reference numbers designate like elements, FIG. 3 illustrates a block diagram of an exemplary imaging device 708 constructed in accordance with an embodiment of the invention. Imager 708 has a pixel array 200 comprised of a plurality of pixels, with each pixel cell being constructed as described above. The row lines are selectively activated by a row driver 210 in response to row address decoder 220. A column driver 260 and column address decoder 270 are also included. The imager is operated by the timing and control circuit 250, which controls address decoders 220, 270. The control circuit 250 also controls the row and column driver circuitry 210, 260. A sample and hold circuit 261 associated with the column driver 260 reads a pixel reset signal (Vᵣₛₜ) and a pixel image signal (V_{sig}) for selected pixels. A differential signal (Vᵣₛₜ−V_{sig}) is produced by differential amplifier 262 for each pixel. The differential signal is digitized by analog-to-digital converter 275 (ADC). The analog-to-digital converter 275 supplies the digitized pixel signals to an image processor 280, which forms and outputs a digital image.

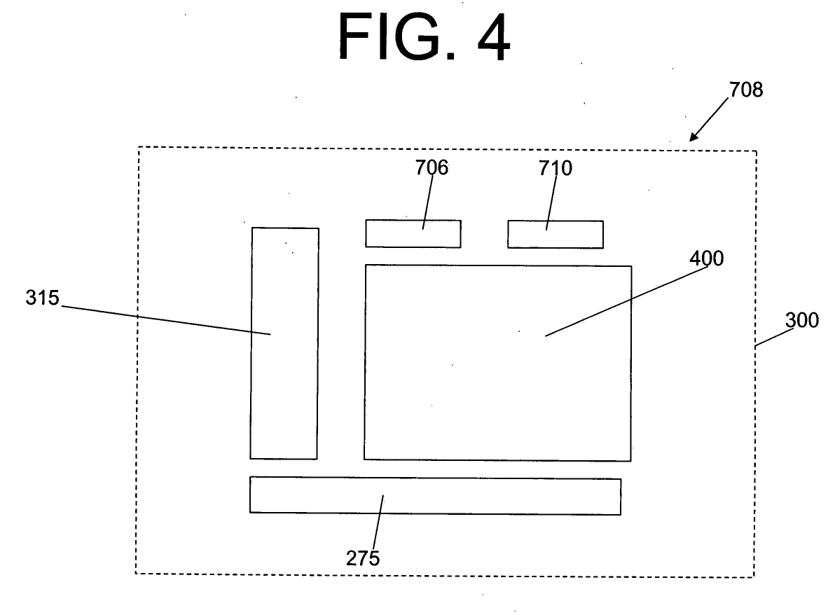

FIG. 4 is a bottom side view of the imaging device 708 showing that the entire bottom side of the imaging device 708 is covered by a thermoelectric cooler 300. In FIG. 4, the coverage area of thermoelectric cooler 300 is depicted by the dotted line. The coverage area of thermoelectric cooler 300 includes the components of the front side of device 708 including periphery logic circuits 315 (e.g., components identified by reference numbers 210, 220, 260 and 270 discussed above with respect to FIG. 3), pixel array 400, input/output (I/O) device 706, random access memory (RAM) 710 and ADC 275.

Thermoelectric cooler 300 is formed by integrating a p/n junction on the back side of the wafer whose front side contains the components of the imaging device and periphery circuits 315, I/O device 706, RAM 710 and ADC converter 275. Thermoelectric cooler 300 is formed prior to processing the front side components. According to an embodiment of the invention, the p/n junction of the thermoelectric cooler 300 can be built on epitaxial silicon grown on the back side of the wafer. The p/n junction is obtained by doping the epitaxial silicon with suitable dopants to create p-type and n-type regions. The back side of the wafer having the thermoelectric cooler 300 is then encapsulated in a thick insulator material, for example, nitride. The encapsulation of the thermoelectric cooler prevents the back side from being affected by processing of the front side. Once the front side processing of the pixel components is completed, the back encapsulated layer may be removed.

According to another embodiment of the invention, thermoelectric cooler 300 is provided with a heat sink formed from a silicon carbine (SiC) layer. SiC has a higher thermal conductivity than silicon and could be useful for particular applications to conduct heat rapidly. A thick layer of SiC can be either deposited or grown epitaxially on the back side of the wafer to subsequently form a thermoelectric cooler. The SiC layer can be a 4H-SiC layer or a 6H-SiC layer. The 4H-SiC and 6H-SiC layers can have a thermal conductivity of about 3.0 to about 3.8 W/cm K@300 k whereas silicon can have a thermal conductivity of about 1.5 W/cm K@300 k). Thermoelectric cooler 300 may also be formed by other methods known in the art.

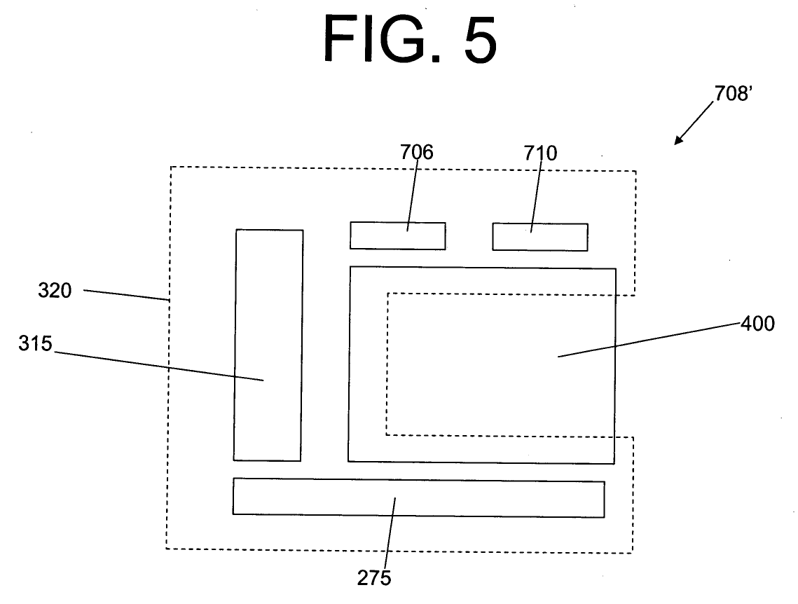

In another embodiment, shown in FIG. 5, an imager 708′ includes a thermoelectric cooler 320 formed as described above with respect to FIG. 4, except that cooler 320 covers select areas of the imager 708′ (instead of the entire imager). In the illustrated embodiment, the thermoelectric cooler 320 covers portions of the imager 708′, excluding most of the pixel array 400. Thermoelectric cooling is therefore targeted to particular components and regions of the imager's 708′ wafer, such as the areas containing the ADC 275 and periphery logic circuits 315.

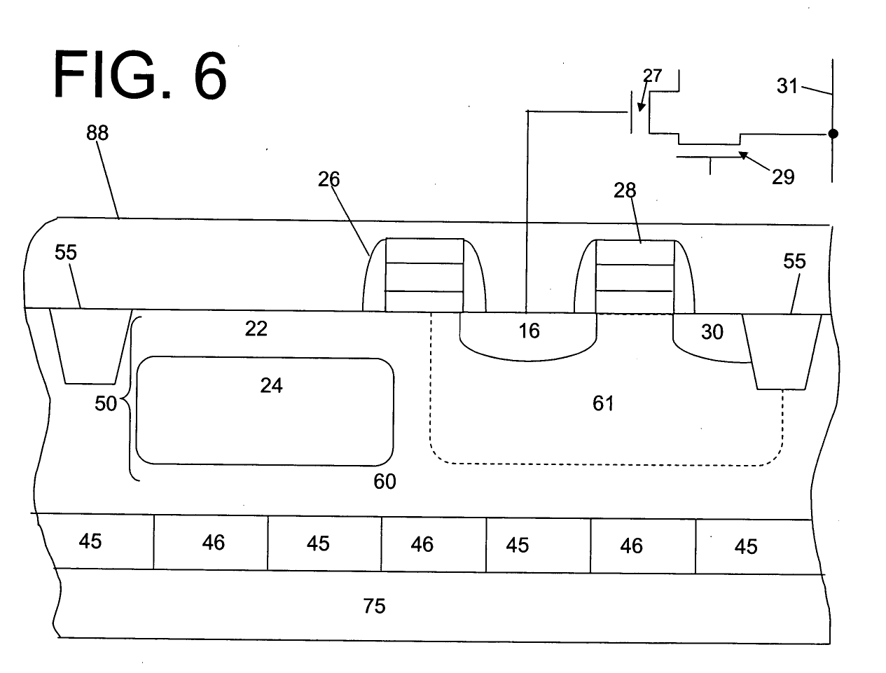

FIG. 6 depicts a pixel according to an exemplary embodiment of the invention. The pixel of FIG. 6 may be used in the imaging device 708 of FIG. 4 or in the imaging device 708′ of FIG. 5. A photoconversion device 50 is formed in a substrate 60 having a doped layer or well 61, which for exemplary purposes is a more heavily doped p-type well with respect to the substrate 60. The photoconversion device 50 is illustratively a photodiode and may be a p-n junction photodiode, a Schottky photodiode, or any other suitable photoconversion device.

The exemplary photodiode 50, as shown in FIG. 6, consists of an n-type region 22 and a p-type region 24. The photodiode 50 is adjacent to an isolation region 55, which is illustratively a shallow trench isolation (STI) region. A floating diffusion region 16 is also formed in well 61. Between the photodiode 50 and the floating diffusion region 16 is a transfer transistor 26 formed over the substrate 60, which operates to transfer charge from the photodiode 50 to the floating diffusion region 16. Regions 45 are doped n-type and regions 46 are doped p-type. The p/n junctions between regions 45 and regions 46 operate as thermoelectric coolers. Region 75 is a passivation layer, which in this embodiment is a nitride layer for exemplary purposes.

The remaining structures shown in FIG. 6 include a reset transistor with associated gate 28 formed over the substrate 60, adjacent the floating diffusion region 16. A source follower transistor 27 and row select transistor 29 with associated gates are also included in the pixel sensor cell but are not shown as cross-sections. They are instead depicted in electrical schematic form with the output of the row select transistor 29 being connected to a column line 31. Although shown in FIG. 6 as a four-transistor (4T) configuration with a transfer transistor 26, the invention can also be utilized in a three-transistor (3T) configuration, without a transfer transistor 26, and in pixels with other transistor number configurations (e.g., 2T, 5T, 6T, 7T, etc).

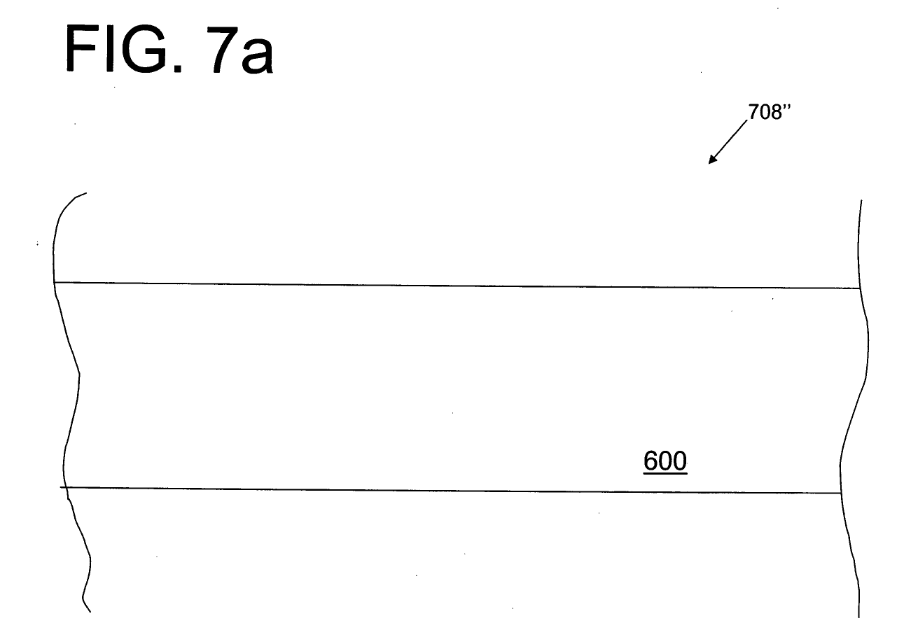

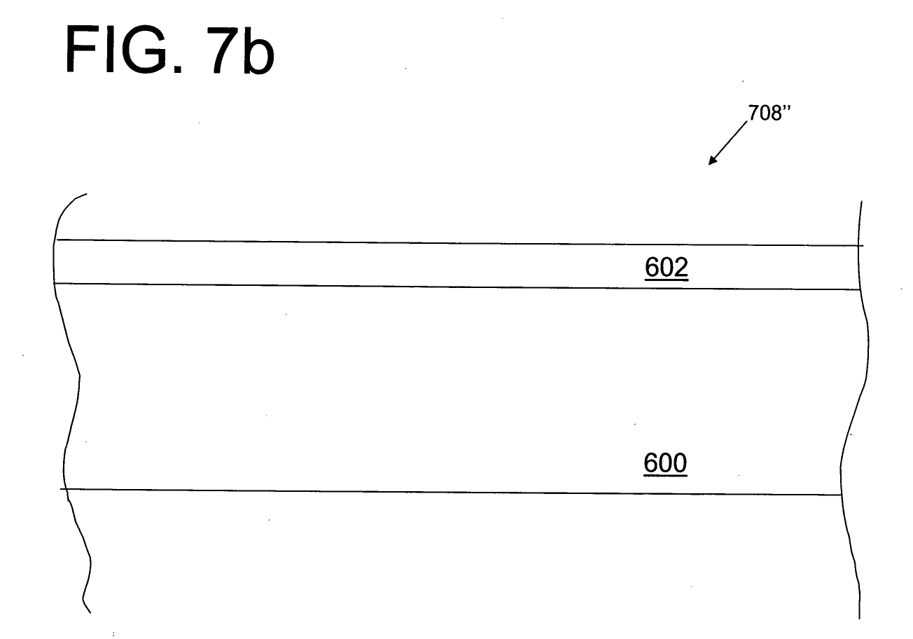

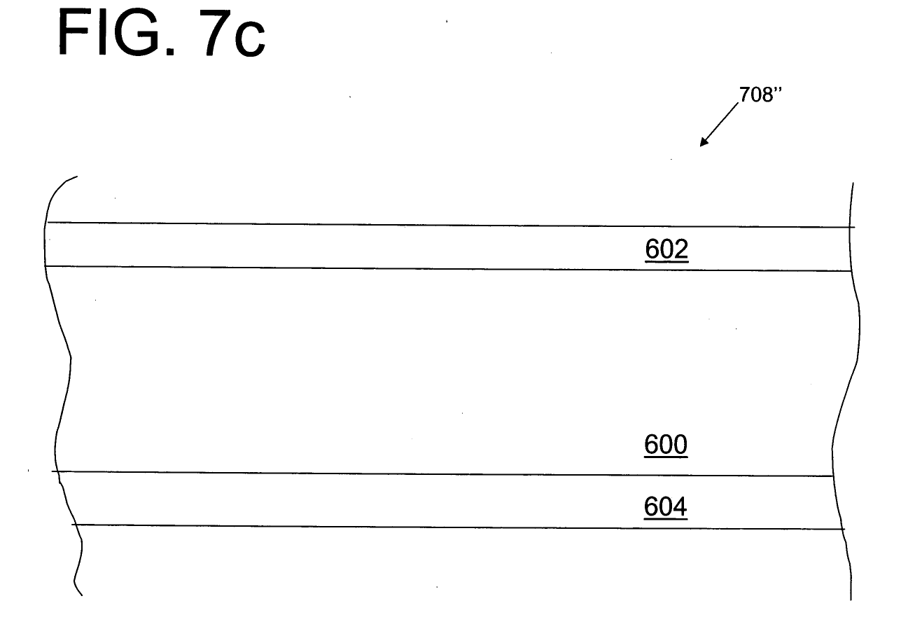

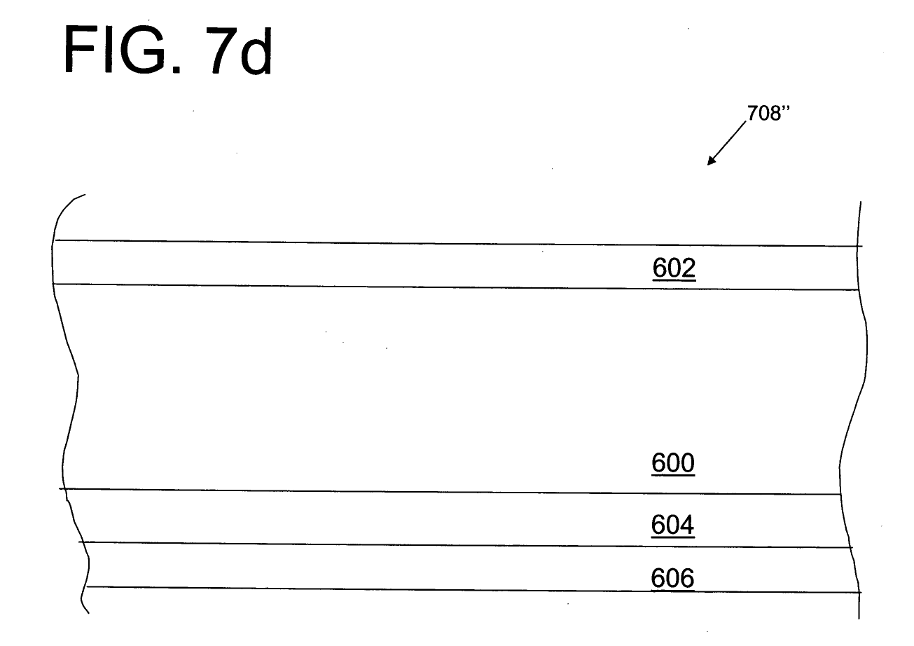

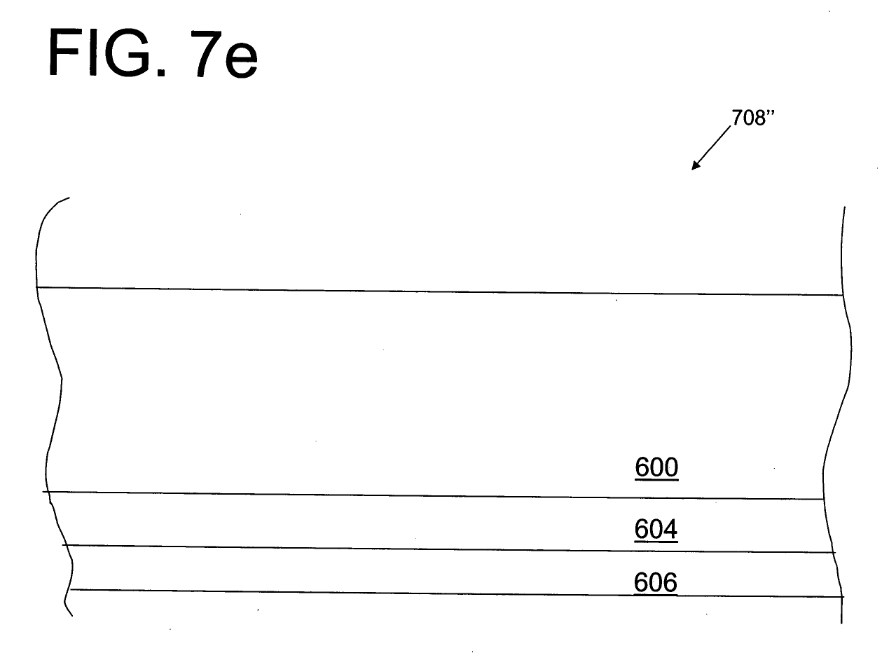

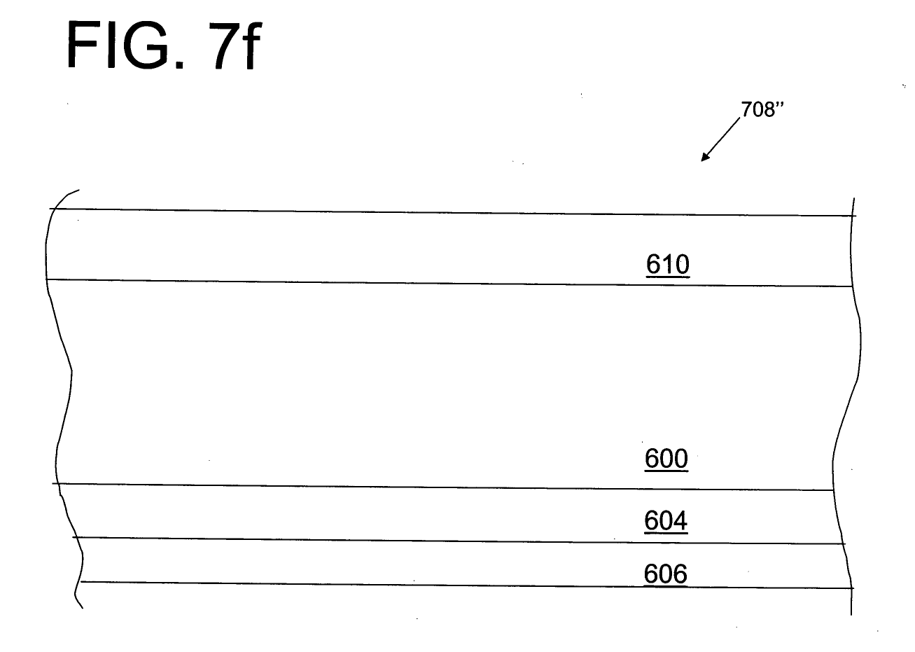

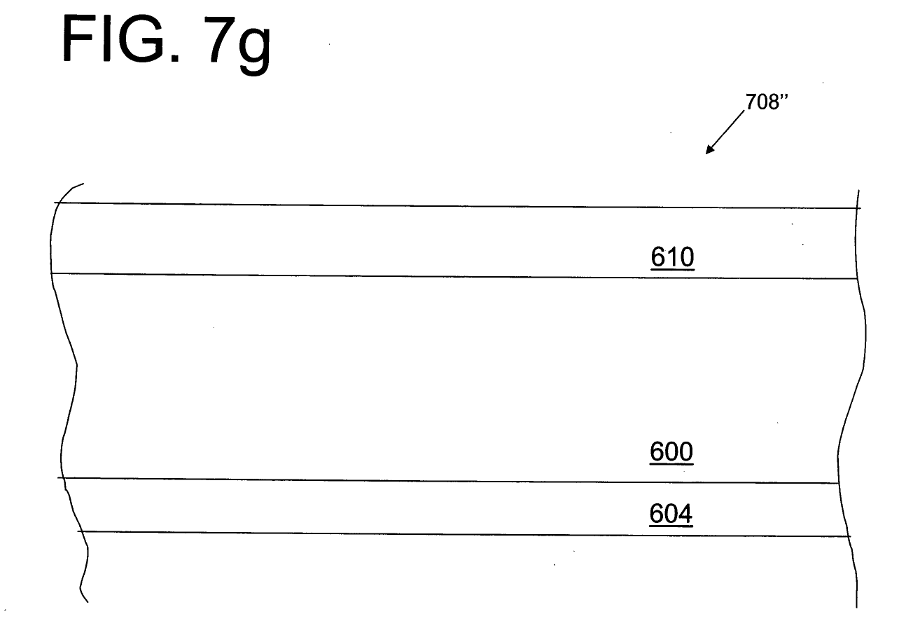

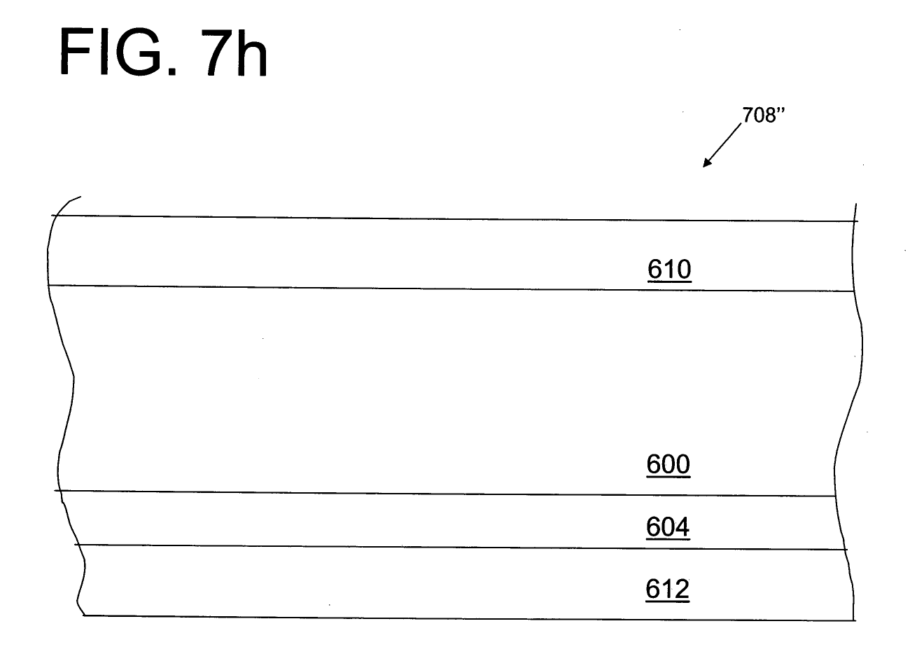

FIGS. 7a-7h illustrate the process of forming another imaging device 708″ according to the invention. In this embodiment, the silicon carbine is formed on the back side of the substrate, but a thermoelectric cooler is not formed. Instead, the device 708″ uses the higher thermal conductivity property of the silicon carbine to dissipate heat. The device 708″ is constructed by providing a bulk silicon wafer 600 (FIG. 7a). The front side of the wafer 600 is covered with an insulator 602 such as nitride or an oxide (FIG. 7b). This insulator 602 will be eventually removed and as such, serves as a sacrificial layer. Back side processing is then performed to grow an epitaxial silicon carbine film 604 (FIG. 7c) on the back side of the wafer 600. The thickness of the silicon carbine film 604 is between approximately 2000 Å to approximately 10000 Å thick. One desired typical thickness could be approximately 5000 Å.

Next, the silicon carbine film 604 is encapsulated by an insulator 606 such as nitride or an oxide (FIG. 7d). The sacrificial insulator 602 is removed (FIG. 7e) and front side processing (as described above) is conducted to form the front side components 610 (shown as a layer for simplicity purposes) of the imaging device 708″ (FIG. 7f). The back side insulator 606 is removed (FIG. 7g) and the as-processed back side of the wafer is bonded to a heat sink at the system level (FIG. 7h).

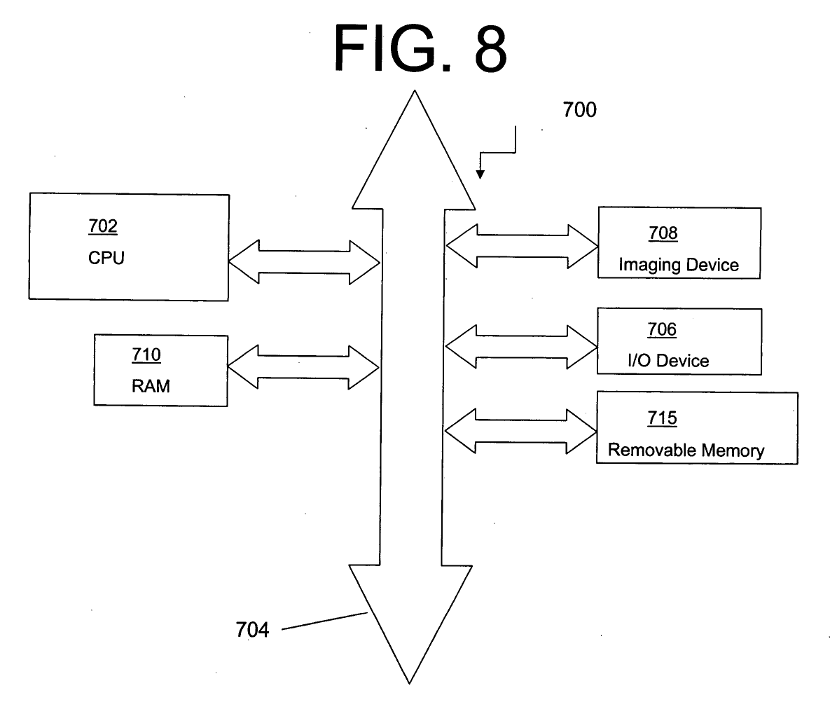

FIG. 8 shows system 700, a processor system which includes an imaging device 708 (FIG. 4) constructed in accordance with an embodiment of the invention. It should be appreciated that the system could instead incorporate the imaging device 708′ of the FIG. 5 embodiment or the device of FIGS. 7a-7h if desired. The processor system 700 is exemplary of a system having digital circuits that could include image sensor devices. Without being limiting, such a system could include a computer system, camera system, scanner, machine vision, vehicle navigation, video phone, surveillance system, auto focus system, star tracker system, motion detection system, image stabilization system, and data compression system.

System 700, for example a camera system, generally comprises a central processing unit (CPU) 702, such as a microprocessor, that communicates with an input/output (I/O) device 706 over a bus 704. Imaging device 708 also communicates with the CPU 702 over the bus 704. The processor-based system 700 also includes random access memory (RAM) 710, and can include removable memory 715, such as flash memory, which also communicate with the CPU 702 over the bus 704. The imaging device 708 may be combined with a processor, such as a CPU, digital signal processor, or microprocessor, with or without memory storage on a single integrated circuit or on a different chip than the processor.

The processes and devices described above illustrate preferred methods and typical devices of many that could be used and produced. The above description and drawings illustrate embodiments, which achieve the objects, features, and advantages of the present invention. However, it is not intended that the present invention be strictly limited to the above-described and illustrated embodiments. Any modifications, though presently unforeseeable, of the present invention that come within the spirit and scope of the following claims should be considered part of the present invention.

What is claimed as new and desired to be protected by letters patent of the United States is:

1. An imaging device comprising:
a substrate having first and second sides;
a pixel array formed in a region on the first side of said substrate; and
a thermoelectric cooler formed on the second side of said substrate

2. The imaging device according to claim 1, wherein said thermoelectric cooler covers substantially all of the second side of the substrate.

3. The imaging device according to claim 1, wherein said thermoelectric cooler covers a portion of the second side of the substrate.

4. The imaging device according to claim 3, wherein the portion includes a portion underneath peripheral circuitry of the device.

5. The imaging device according to claim 4, wherein the peripheral circuitry includes an analog-to-digital converter.

6. The imaging device according to claim 3, wherein the portion does not include a region underneath said array.

7. The imaging device according to claim 1, wherein said thermoelectric cooler comprises a doped substrate.

8. The imaging device according to claim 7, wherein said doped substrate includes at least one p/n junction.

9. The imaging device according to claim 1, wherein said thermoelectric cooler comprises epitaxial silicon.

10. The imaging device according to claim 1, wherein said thermoelectric cooler comprises silicon carbine.

11. The imaging device according to claim 1, wherein the first side is a front side of the substrate.

12. The imaging device according to claim 1, wherein the second side is a back side of the substrate.

13. The imaging device according to claim 1, wherein the second side is a back side of the substrate and silicon carbine is used to build a p/n junction in the substrate.

14. A CMOS imager integrated circuit comprising:
an imaging device including:
a substrate having first and second sides;
at least one first doped layer formed on the first side of said substrate;
a thermoelectric cooler formed on the second side of said substrate;
an array of pixel sensor cells formed in said doped layer; and
peripheral circuitry formed in said substrate on the first side of said substrate.

15. The integrated circuit of claim 14, wherein said thermoelectric cooler covers substantially all of the second side of the substrate.

16. The integrated circuit of claim 14, wherein said thermoelectric cooler covers a portion of the second side of the substrate, the portion being underneath said peripheral circuitry.

17. A CMOS imager integrated circuit comprising:
an imaging device including:
a substrate having a front side and a back side;
at least one first doped layer formed on the front first side of the substrate;
a layer of silicon carbine formed on the back side of said substrate;
an array of pixel sensor cells formed in said doped layer; and
peripheral circuitry formed in said substrate on the front side of said substrate.

18. A processing system comprising:
a processor; and
an imager coupled to said processor, said imager comprising:
a substrate having first and second sides;
a pixel array formed on the first side of said substrate, said array having a doped layer;
peripheral circuitry formed in said substrate on the first side of substrate adjacent said array; and
a thermoelectric cooler formed on the second side of said substrate.

19. The system according to claim 18, wherein said thermoelectric cooler covers substantially all of the second side of the substrate.

20. The system according to claim 18, wherein said thermoelectric cooler covers a portion of the second side of the substrate.

21. The system according to claim 20, wherein the portion includes a portion underneath said peripheral circuitry.

22. The system according to claim 21, wherein the peripheral circuitry includes an analog-to-digital converter.

23. The system according to claim 20, wherein the portion does not include a region underneath said array.

24. The system according to claim 18, wherein said thermoelectric cooler comprises a doped substrate.

25. The system according to claim 24, wherein said doped layer includes at least one p/n junction.

26. The system according to claim 18, wherein said thermoelectric cooler comprises epitaxial silicon.

27. The system according to claim 18, wherein said thermoelectric cooler comprises silicon carbine.

28. The system according to claim 18, wherein the first side is a front side of the substrate.

29. The system according to claim 18, wherein the second side is a back side of the substrate.

30. The system according to claim 18, wherein the second side is a back side of the substrate and silicon carbine is used to build a p/n junction in the substrate.

31. A method for forming an imaging device comprising:
forming at least one doped layer in a substrate on a first surface of the imaging device; and
forming a thermoelectric cooler in a substrate on a second surface of the imaging device; and
forming an array of pixel sensor cells, peripheral transistors and signal processing circuitry in said doped layer on the first side of said imaging device in an area over the thermoelectric cooler.

32. The method according to claim 31, wherein said thermoelectric cooler covers substantially all of the second side of the substrate.

33. The method according to claim 31, wherein said thermoelectric cooler covers a portion of the second side of the substrate.

34. The method according to claim 31, wherein the portion of the imaging device includes a portion underneath said peripheral circuitry.

35. The method according to claim 34, wherein the peripheral circuitry includes an analog-to-digital converter.

36. The method according to claim 35, wherein the portion does not include a region comprising said array.

37. The method according to claim 31, wherein said thermoelectric cooler comprises a doped substrate.

38. The method according to claim 37, wherein said doped substrate includes at least one p/n junction.

39. The method according to claim 31, wherein said thermoelectric cooler comprises epitaxial silicon.

40. The method according to claim 31, wherein said thermoelectric cooler comprises silicon carbine.

41. A method of operating a semiconductor imaging device comprising:
generating digital information within a pixel; and
creating a Peltier effect to remove heat from the pixel.

42. A method of making semiconductor imaging devices comprising the acts of:
locating cooler elements on a back side of a wafer; and
subsequently, forming pixel elements on a front side of said wafer.

43. The method of claim of claim 42, wherein the cooler elements include p/n junctions.

44. A method of making a semiconductor imaging device comprising the acts of:
providing a wafer;
covering a front side of the wafer with a first insulator;
growing an epitaxial silicon carbine film on a back side of the wafer;
encapsulating the silicon carbine film with a second insulator;
removing the first insulator;
performing front side processing to form front side components of the imaging device;
removing the second insulator; and
bonding the back side of the wafer to a heat sink.

45. The method of claim 44 wherein a thickness of the silicon carbine film is between approximately 2000 Å to approximately 10000 Å thick.

46. The method of claim 44 wherein a thickness of the silicon carbine film is approximately 5000 Å.
